(19) United States
(12) Patent Application Publication
(10) Pub. No.: US 2013/0328945 A1
(43) Pub. Date: Dec. 12, 2013

(54) DISPLAY DEVICE AND METHOD OF OPERATING THE SAME

(71) Applicant: Ki-Wook KIM, Yongin-City (KR)

(72) Inventor: Ki-Wook KIM, Yongin-City (KR)

(21) Appl. No.: 13/690,436

(22) Filed: Nov. 30, 2012

(30) Foreign Application Priority Data
Jun. 11, 2012 (KR) 10-2012-0062353

(51) Int. Cl. H01L 33/08; G09G 3/36; G02F 1/1362

(52) U.S. Cl. CPC H01L 33/08; G02F 1/136286; G09G 3/36
USPC 345/690; 257/88; 349/42

(57) ABSTRACT

A display device includes a first substrate, a display unit, an encapsulation structure, and a light transmittance converter. Each of the pixels in the display unit includes a first region from which light is emitted in a first direction and a second region, adjacent to the first region, through which external light is transmitted. The encapsulation structure covers and encapsulates the display unit, and includes at least one first layer having an inorganic material and at least one second layer having an organic material. The light transmittance converter is adjacent to the first substrate or the encapsulation structure, is on an outer side of the display unit in a second direction that is opposite to the first direction, and converts transmittance of the external light transmitted through the second region.

### CROSS-REFERENCE TO RELATED PATENT APPLICATION

This application claims priority under 35 U.S.C. §119 to Korean Patent Application No. 10-2012-0062353, filed on Jun. 11, 2012, in the Korean Intellectual Property Office, the disclosure of which is incorporated herein in its entirety by reference.

### BACKGROUND

An organic light emitting display device has excellent characteristics in respect of a viewing angle, a contrast ratio, a response speed, consumption power, etc. Organic light emitting display devices may be widely used in many fields including personal portable devices such as MP3 players and mobile phones, and televisions (TVs). The organic light emitting display device is self-emissive, and may be thin and light-weight since it does not require an additional light source.

### SUMMARY

Embodiments may be realized by providing a display device that includes a first substrate; a display unit that is formed on a first surface of the first substrate and includes a plurality of pixels, wherein each of the pixels comprises a first region from which light is emitted in a first direction and a second region that is adjacent to the first region and through which external light is transmitted; an encapsulation structure that contacts the first surface of the first substrate so as to cover and encapsulate the display unit, and includes at least one first layer including an inorganic material and at least one second layer including an organic material; and a light transmittance converter that is adjacent to the first substrate or the encapsulation structure and is disposed on the outer side of the display unit in a second direction that is opposite to the first direction, and converts transmittance of external light that transmits through the second region.

The display unit may include a pixel circuit unit that is formed on the first surface of the first substrate, includes at least one thin film transistor, and is disposed in the first region; a first electrode that is electrically connected to the pixel circuit unit, is disposed in the first region, is disposed adjacent to the pixel circuit unit so as not to overlap with the pixel circuit unit, and comprises a transparent conductive material; a second electrode that faces the first electrode and is disposed at least in the first region; and an organic layer that is interposed between the first electrode and the second electrode and comprises a light emitting layer.

The light transmittance converter may be disposed on the outer side of the encapsulation structure. The light transmittance converter may include a common electrode that is adjacent to the encapsulation structure; a second substrate that faces the encapsulation structure; a plurality of control electrodes that are disposed on a portion of the second substrate facing the encapsulation structure and are disposed to overlap with the second region; and liquid crystals disposed between the common electrode and the second substrate.

The display device may further include an optical filter adjacent to a second surface of the first substrate. The second region may be overlapped with the first region.

The display unit may include a pixel circuit unit that is formed on the first surface of the first substrate, includes at least one thin film transistor, and is disposed in the first region; a first electrode that is electrically connected to the pixel circuit unit, is disposed in the first region so as to overlap with the pixel circuit unit to cover the pixel circuit unit, and includes a reflection layer having a conductive material that is capable of reflecting light; a second electrode that is formed to be light-transmissive so as to emit light in a direction opposite to the first electrode and that faces the first electrode; and an organic layer that is interposed between the first electrode and the second electrode and comprises a light emitting layer.

The light transmittance converter may be adjacent to a second surface of the first substrate. The light transmittance converter may include a common electrode that is adjacent to the second surface of the first substrate; a second electrode that faces the second surface of the first substrate; a plurality of control electrodes that are disposed on a portion of the second substrate facing the first substrate and are disposed to overlap with the second region; and liquid crystals disposed between the common electrode and the second substrate.

The display device may further include an optical filter that is adjacent to the encapsulation structure. In the light transmittance converter, a sum of reflectivity and transmittance of the external light may be 1. The light transmittance converter may include a pair of transparent electrode layers to which power is applied; and an electrochromic material layer that is disposed between the pair of transparent electrode layers and includes an electrochromic material whose phase is changed by power applied to the transparent electrode layer to adjust light reflectivity of the electrochromic material layer.

Embodiments may also be realized by providing a method of operating a display device, the display device including a first substrate; a display unit that is formed on a first surface of the first substrate and includes a plurality of pixels, wherein each of the pixels includes a first region from which light is emitted in a first direction and a second region that is adjacent to the first region and through which external light is transmitted; an encapsulation structure that contacts the first surface of the first substrate so as to cover and encapsulate the display unit, and includes at least one first layer including an inorganic material and at least one second layer including an organic material; and a light transmittance converter that is adjacent to the first substrate or the encapsulation structure and is disposed on the outer side of the display unit in a second direction that is opposite to the first direction, and converts transmittance of external light that transmits through the second region, wherein a first mode, a second mode, and a third mode are implemented by adjusting transmittance of the external light that transmits through at least the second region by applying first through third power that are different from one another, to the light transmittance converter.

The first mode may include applying the first power to the light transmittance converter; displaying an image in the first direction by using the display unit; and allowing the external light to transmit through the display unit and the light transmittance converter in the first direction. The second mode may include applying the second power to the light transmittance converter; displaying an image in the first direction by using the display unit; and allowing the external light not to transmit through the display unit in the first direct direction.

The third mode may include applying the third power to the light transmittance converter; displaying an image in the first direction by using the display unit; allowing a portion of the external light to transmit through the display unit in the first direction; and allowing a portion of the external light to be reflected by the light transmittance converter in the second direction. A sum of transmittance and reflectivity of the external light may be 1.

### BRIEF DESCRIPTION OF THE DRAWINGS

Features will become apparent to those of ordinary skill in the art by describing in detail exemplary embodiments thereof with reference to the attached drawings in which:

FIG. 1 is a schematic view of a display device according to an exemplary embodiment;

FIGS. 2 and 3 illustrate examples of pixels included in the display device of FIG. 1, according to exemplary embodiments;

FIG. 4 is a cross-sectional view of a sub-pixel from among sub-pixels illustrated in FIGS. 2 and 3;

FIG. 5 illustrates another example of a pixel included in the display device of FIG. 1, according to an exemplary embodiment;

FIG. 6 is a cross-sectional view of a sub-pixel from among sub-pixels illustrated in FIG. 5;

FIG. 7 is a schematic cross-sectional view of a display device according to an exemplary embodiment;

FIGS. 8 and 9 illustrate examples of pixels included in the display device of FIG. 7, according to the exemplary embodiments;

FIG. 10 is a cross-sectional view of a sub-pixel from among sub-pixels illustrated in FIGS. 8 and 9;

FIGS. 11 through 13 illustrate a method of operating a display device according to respective modes according to an exemplary embodiment; and

FIG. 14 is a schematic view of a light transmittance converter included in a display device according to an exemplary embodiment.

### DETAILED DESCRIPTION

Example embodiments will now be described more fully hereinafter with reference to the accompanying drawings; however, they may be embodied in different forms and should not be construed as limited to the embodiments set forth herein. However, this is not intended to limit the embodiments to particular modes of practice, and it is to be appreciated that all changes, equivalents, and substitutes that do not depart from the spirit and technical scope of the present invention are encompassed in the present invention. In the description, certain detailed explanations of related art are omitted when it is deemed that they may unnecessarily obscure the essence of the embodiments.

While such terms as “first,” “second,” etc., may be used to describe various components, such components must not be limited to the above terms. The above terms are used only to distinguish one component from another.

The terms used in the present specification are merely used to describe exemplary embodiments, and are not intended to limit the embodiments. An expression used in the singular encompasses the expression of the plural, unless it has a clearly different meaning in the context. In the present specification, it is to be understood that the terms such as “including” or “having,” etc., are intended to indicate the existence of the features, numbers, steps, actions, components, parts, or combinations thereof disclosed in the specification, and are not intended to preclude the possibility that one or more other features, numbers, steps, actions, components, parts, or combinations thereof may exist or may be added.

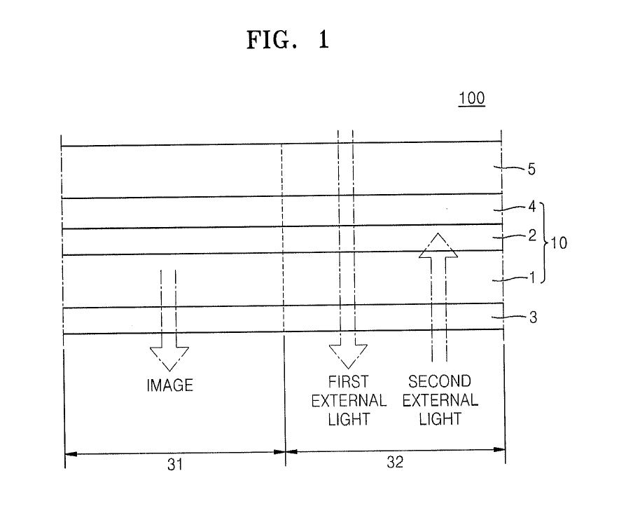

FIG. 1 is a schematic view of a display device 100 according to an exemplary embodiment.

Referring to FIG. 1, the display device 100 includes a display unit 10, an optical filter 3, and a light transmittance converter 5.

The display unit 10 may be a bottom emission type organic light emitting display device, and may include a first substrate 1, a display portion 2 formed on the first substrate 1, and an encapsulation structure 4 that encapsulates the display portion 2. The display portion 2 is partitioned into a plurality of pixels, and each pixel includes a first region 31 from which light, e.g., an image, is emitted toward the first substrate 1 and a second region 32 which is adjacent to the first region 31 and through which external light is transmitted.

The optical filter 3 is disposed outside the first substrate 1 from which light is emitted in the display unit 10. The optical filter 3 transmits circularly polarized light that rotates in a predetermined direction. Accordingly, the optical filter 3 may be formed by combining, e.g., a linear polarization filter and a Lambda/4 retarder which is a phase converter, or may be a circular polarization filter.

The light transmittance converter 5 is disposed on the outer side of the encapsulation structure 4, which is in a direction that the display unit 10 is not configured to emit an image/light. The light transmittance converter 5 may convert transmittance or reflectivity of external light according to modes. The light transmittance converter 5 may be a liquid crystal display device capable of varying light transmittance or reflectivity through changes of arrangement of liquid crystals according to an applied electrical field, or may be an electrochromic device capable of varying light transmittance or reflectivity through changes in a state of an electrochromic material according to applied power.

The light transmittance converter 5 may be formed to satisfy a constraint condition that a sum of reflectivity and transmittance of light is always about 1 or 1 (or about 100% or 100%). A contrast ratio of the display device 100 is expressed in Equation 1 below, and control of the contrast ratio of the display device 100 may be simplified using the light transmittance converter 5. If this constraint condition is not provided, the contrast ratio of the display device 100 may be controlled by adjusting two variables, that is, reflectivity and transmittance. However, as the light transmittance converter 5 has the above-described restriction condition, the contrast ratio of the display device 100 may be easily controlled by adjusting only one of the two variables such as light reflectivity and transmittance.

$$contrastratio ∝ \frac{1}{reflectivity \times ( 1 - transmittance )} \qquad [ Equation 1 ]$$

According to the current embodiment, when the light transmittance converter 5 is in an external light transmission mode, a user located at a portion where an image is formed may observe the image on the outer side of first substrate 1, e.g., through the first external light that is transmitted from the outer side of the encapsulation structure 4 toward the outer side of the first substrate 1. Also, second external light transmits through the display device 100 and is directed to the opposite side of the user, and thus does not affect the contrast ratio of the display device 100. The first external light is external light emitted in the same direction as that of the image, and the second external light is external light emitted in the opposite direction to the first external light.

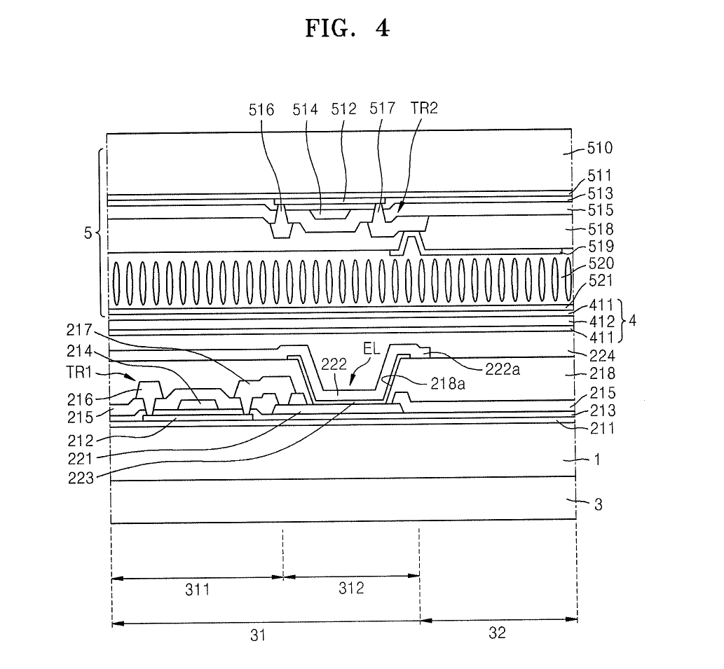

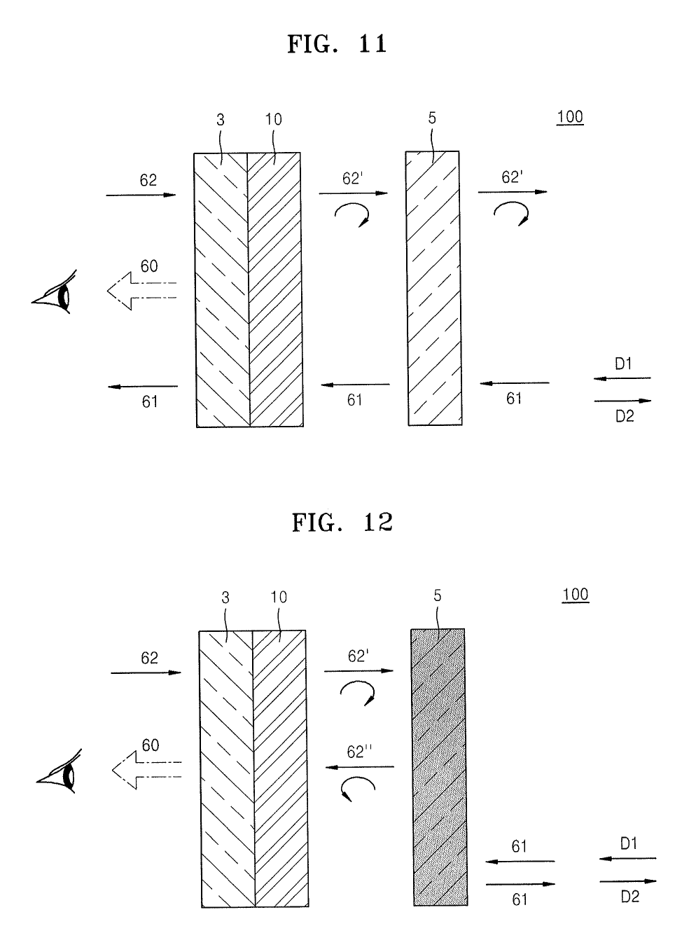

When the light transmittance converter 5 is in an external light block mode, the first external light is substantially blocked and/or not able to be transmitted through the display device 100. However, in this mode, the second external light that is transmitted from the outer side of the first substrate 1 toward the outer side of a second substrate 510 (see FIG. 4) could be reflected by the light transmittance converter 5 and emitted again toward the outer side of the first substrate 1, thereby degrading the contrast ratio of the display device 100. Accordingly, exemplary embodiments relate to including the optical filter 3 to reduce the possibility of and/or prevent the decrease in the contrast ratio. An operation of the display device 100 will be described in detail later with reference to FIGS. 11 through 13.

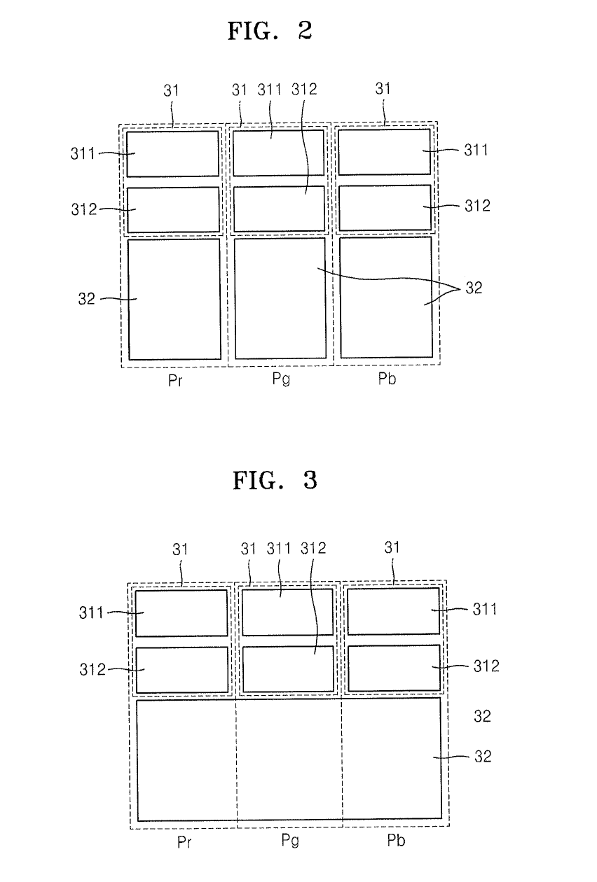

FIG. 2 illustrates an example of a pixel included in the display unit 10 illustrated in FIG. 1 according to the exemplary embodiment. FIG. 3 illustrates another example of a pixel included in the display unit 10 illustrated in FIG. 1 according to the exemplary embodiment.

A pixel may include a plurality of sub-pixels, e.g., a pixel may include a red sub-pixel Pr, a green sub-pixel Pg, and a blue sub-pixel Pb.

Each of the sub-pixels Pr, Pg, and Pb includes a first region 31 and a second region 32. The first region 31 includes a pixel circuit unit 311 and a light emitting unit 312. The pixel circuit unit 311 and the light emitting unit 312 may be disposed adjacent to each other while not being overlapped by each other in order to be formed in a non-overlapping relationship. In this case, when the light emitting unit 312 emits light toward the first substrate 1 in a bottom emission manner, a path of light may be not disturbed by the pixel circuit unit 311.

The second region 32 through which external light is transmitted is disposed adjacent to the first region 31, e.g., in a non-overlapping relationship.

As illustrated in FIG. 2, the second region 32 may be included in each of the sub-pixels Pr, Pg, and Pb, or as illustrated in FIG. 3, the second regions 32 may be formed as a single portion over the sub-pixels Pr, Pg, and Pb. In other words, when viewing the display portion 2 as a whole, pixels may respectively include a plurality of first regions 31 which are spaced apart from one another while including the second regions 32 as a common area. According to the embodiment of FIG. 3, a surface area of the second region 32 through which external light is transmitted may be increased, and thus transmittance of the entire display portion 2 may be increased.

The second regions 32 of the red sub-pixel Pr, the green sub-pixel Pg, and the blue sub-pixel Pg are illustrated as a single portion in FIG. 3, but the embodiments are not limited thereto. For example, the second regions 32 of any two adjacent sub-pixels from among the red sub-pixel Pr, the green sub-pixel Pg, and the blue sub-pixel Pg may be formed to be a single portion.

FIG. 4 is a cross-sectional view of a sub-pixel from among the red, green, and blue sub-pixels Pr, Pg, and Pb illustrated in FIGS. 2 and 3. The light transmittance converter 5 illustrated in FIG. 4 is a liquid crystal display device.

As illustrated in FIG. 4, a first thin film transistor TR1 is disposed in the pixel circuit unit 311, but the embodiments are not limited to the single thin film transistor as illustrated in FIG. 4. For example, a plurality of thin film transistors including the first thin film transistor TR1 may be included. Besides the thin film transistor, at least one storage capacitor may be further included in the pixel circuit unit 311, and wirings such as a scan line, a data line, and a Vdd line connected to the pixel circuit unit 311 may be further included.

An organic light emitting diode EL which is a light emitting device is disposed in the light emitting unit 312. The organic light emitting diode EL is electrically connected to the first thin film transistor TR1 of the pixel circuit unit 311.

First, a first buffer layer 211 is formed on the first substrate 1, and the pixel circuit unit 311 including the first thin film transistor TR1 is formed on the first buffer layer 211.

The first buffer layer 211 may prevent penetration of impurity elements and planarize a surface of the first substrate 1, and may be formed of various materials that are capable of performing these functions. The first buffer layer 211 may be formed of an insulator having a high light transmittance. For example, the first buffer layer 211 may be formed of an inorganic material such as silicon oxide, silicon nitride, silicon oxynitride, aluminum oxide, aluminum nitride, titanium oxide, or titanium nitride; organic material such as polyimide, polyester, or acryl; or a stacked structure of these materials. The first buffer layer 211 may be omitted.

A first semiconductor active layer 212 is formed on the first buffer layer 211. The first semiconductor active layer 212 may be formed of polycrystalline silicon, but is not limited thereto. For example, the first semiconductor active layer 212 may be formed of an oxide semiconductor. For example, the first semiconductor active layer 212 may be a G-I—Z—O layer [(In₂O₃)a(Ga₂O₃)b(ZnO)c layer] (where a, b, and c are real numbers satisfying a≧0, b≧0, and c>0). When forming the first semiconductor active layer 212 using an oxide semiconductor, light transmittance of the pixel circuit unit 311 from among the first region 31 may be further increased, and accordingly, the entire external light transmittance of the display portion 2 may be increased.

A first gate insulating layer 213 may be formed on the first buffer layer 211 so as to cover the first semiconductor active layer 212, and a first gate electrode 214 is formed on the first gate insulating layer 213.

A first interlayer insulating layer 215 is formed on the first gate insulating layer 213 to cover the first gate electrode 214. A first source electrode 216 and a first drain electrode 217 are formed on the first interlayer insulating layer 215 to contact the first semiconductor active layer 212 via contact holes.

A structure of the first thin film transistor TR1 is not limited to the above, and various thin film transistor structures may be used.

A first insulating layer 218 is formed to cover the first thin film transistor TR1. The first insulating layer 218 may be a single insulating layer or a plurality of insulating layers whose upper surface is planarized. The first insulating layer 218 may be formed of an inorganic material and/or an organic material.

A first electrode 221 of the organic light emitting diode EL that is electrically connected to the first thin film transistor TR1 is formed on the first gate insulating layer 213. The first electrode 221, e.g., having an independent island form, is formed in each sub-pixel. The first electrode 221 may be disposed in the light emitting unit 312 in the first region 31 and may be disposed not to overlap with the pixel circuit unit 311, e.g., so as to be excluded from the pixel circuit unit 311 and included only in the light emitting unit 312

The first interlayer insulating layer 215 covers, e.g., overhangs, edges of the first electrode 221, and does not cover the central portion of the first electrode 221.

The first insulating layer 218 is formed to cover edges of the first electrode 221, and has a first opening 218a exposing the central portion of the first electrode 221. The first insulating layer 218 may be included to cover the first region 31. However, the first insulating layer 218 may not cover the entire first region 31, e.g., the first insulating layer 218 may cover at least a portion of, particularly, the edges of the first electrode 221. The first insulating layer 218 may also be formed in the second region 32, e.g., to cover an entirety of the second region. Accordingly, an external light transmission efficiency of the second region 32 may be further increased. However, embodiments are not limited thereto, e.g., the first insulating layer 218 may be formed to have an opening corresponding to at least a portion of the second region 32.

An organic layer 223 and a second electrode 222 are sequentially stacked on the first electrode 221 that is exposed through the first opening 218a. The second electrode 222 faces the first electrode 221, covers the organic layer 223 and portions the first insulating layer 218, and is disposed in the first region 31. The second electrode 222 may be formed to have a second opening 222a that corresponds to at least a portion of the second region 32. Accordingly, external transmission efficiency of the second region 32 may be further increased.

The organic layer 223 may be a low-molecular or polymer organic layer. When a low-molecular organic layer is used, a single structure or a complex structure including a hole injection layer (HIL), a hole transport layer (HTL), an emission layer (EML), an electron transport layer (ETL), an electron injection layer (EIL) may be stacked. Examples of organic materials include copper phthalocyanine (CuPc), N,N′-Di(naphthalene-1-yl)-N,N-diphenyl-benzidine (NPB), and tris-8-hydroxyquinoline aluminum (Alq3). The low molecular organic layer may be formed using a vacuum deposition method. The HIL, the HTL, the ETL, and the EIL are common layers and may be commonly applied to red, green, and blue pixels.

The first electrode 221 functions as an anode electrode, and the second electrode 222 may function as a cathode electrode, and polarities of the first electrode 221 and the second electrode 222 may be exchanged.

According to the current embodiment, the first electrode 221 may be a transparent electrode, and the second electrode 222 may be a reflection electrode. The first electrode 221 may include a transparent conductive material such as ITO, IZO, ZnO, or In₂O₃. The second electrode 222 may be formed of, e.g., Ag, Mg, Al, Pt, Pd, Au, Ni, Nd, Ir, Cr, Li, or Ca. Accordingly, the organic light emitting diode EL may be a bottom emission type which forms an image toward the first electrode 221. In this case, the second electrode 222 may be formed to have a sufficient thickness to minimize and/or prevent a voltage drop in the entire display portion 2, and thus may be sufficient to be applied to the display device 100 having a large surface area.

A protection layer 224 may be formed on the second electrode 222 and the first insulating layer 218. The protection layer 224 may reduce the possibility of and/or prevent damage of the second electrode 222. The protection layer 224 may be formed of a highly light-transmissive material such as LiF, lithium quinolate, or Alq₃.

An encapsulation structure 4 including at least one first layer 411 and at least one second layer 412 is formed on the protection layer 224. The first layer 411 includes an inorganic material, and the second layer 412 includes an organic material.

The inorganic material may include at least one of silicon oxide, silicon nitride, silicon oxynitride, aluminum oxide, aluminum nitride, aluminum oxynitride, zinc oxide, phosphor oxide, boron phosphate, zinc fluoride, niobe oxide, and tungsten oxide, but is not limited thereto.

The organic material may include acryl or polyimide, but is not limited thereto.

The first layer 411 and the second layer 412 may preferably be alternately stacked. Referring to FIG. 4, the first layers 411 may be formed in a two-layer fashion, in which the second layer 412 is interposed between two of the first layers 411. However, embodiments of the encapsulation structure 4 are not limited thereto, e.g., the number of the first layers 411 and the number of the second layer 412 may be varied. In the embodiments, the first layers 411 including an inorganic material may be disposed as the outermost portions of opposing sides of the encapsulation structure 4.

A common electrode 521 of the light transmittance converter 5, which may be a liquid crystal display device, is formed on the encapsulation structure 4. The common electrode 521 may include a transparent conductive material such as ITO, IZO, ZnO, or In₂O₃.

The light transmittance converter 5 as a liquid crystal display device includes a second substrate 510 that faces the first substrate 1. A second buffer layer 511 is formed on a surface of the second substrate 510 that faces the first substrate 1. A circuit unit including a second thin film transistor TR2 is formed on the second buffer layer 511. The second thin film transistor TR2 may be substantially similar to the first thin film transistor TR1.

The second buffer layer 511 may prevent penetration of impurity elements and planarize a surface of the second substrate 510, and may be formed of various materials that may perform these functions. The second buffer layer 511 may be formed of an insulator having a high light transmittance. For example, the second buffer layer 511 may be formed of an inorganic material such as silicon oxide, silicon nitride, silicon oxynitride, aluminum oxide, aluminum nitride, titanium oxide, or titanium nitride; an organic material such as polyimide, polyester, or acryl; or a stack structure of these materials. The second buffer layer 511 may be omitted.

A second semiconductor active layer 512 is formed on the second buffer layer 511. The second semiconductor active layer 512 may be formed of polycrystalline silicon or amorphous silicon. However, embodiments are not limited thereto, e.g., but the second semiconductor active layer 512 may be formed of an oxide semiconductor.

A second gate insulating layer 513 is formed on the second buffer layer 511 to cover the second semiconductor active layer 512, and a second gate electrode 514 is formed on the second gate insulating layer 513.

A second interlayer insulating layer 515 is formed on the second gate insulating layer 513 to cover the second gate electrode 514, and a second source electrode 516 and a second drain electrode 517 are respectively formed on the second interlayer insulating layer 515 to contact the second semiconductor active layer 512 via contact holes.

A structure of the second thin film transistor TR2 as described above is not limited thereto, and various thin film transistor structures may be applied.

A passivation layer 518 is formed to cover the second thin film transistor TR2. The passivation layer 518 whose upper surface is planarized may be a single insulating layer or a plurality of insulating layers. The passivation layer 518 may be formed of an inorganic material and/or an organic material.

A control electrode 519 is formed on the passivation layer 518, and the control electrode 519 is electrically connected to the second thin film transistor TR2 via a hole formed in the passivation layer 518. The control electrode 519 is formed at a position to correspond to at least a portion of the second region 32. The second thin film transistor TR2 may be formed to correspond to the light emitting unit 312 with respect to the first substrate 1.

After sequentially forming the second thin film transistor TR2, the passivation layer 518, and the control electrode 519 on the surface of the second substrate 510, the first substrate 1 and the second substrate 510 are separate from each other. Thereafter, the first substrate 1 and the second substrate 510 bonded to each other after interposing liquid crystals 520 therebetween so that the second substrate 510 faces the first substrate 1. Accordingly, the control electrode 519 of the second substrate 510 is disposed to face the common electrode 521 formed on the encapsulation structure 4 and the liquid crystals 520 are interposed between the control electrode 519 and the common electrode 521.

When the light transmittance converter 5, which is the liquid crystal device, is in an external light block mode, the control electrode 519 is turned on (or off) so that transmission of external light through the second region 32 is blocked by the liquid crystals 520. When the light transmittance converter 5 is in an external light transmission mode, the control electrode 519 is turned off (or on) so that external light may be transmitted through the second region 32.

According to exemplary embodiments, the display device 100 of a bottom emission type including the display unit 10 and the light transmittance converter 5 may be manufactured using the simple and cost-effective process while reducing the total thickness of the display device 100.

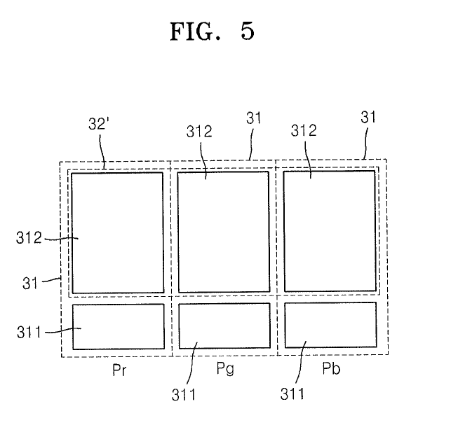

FIG. 5 illustrates another example of a pixel included in the display unit 10 of FIG. 1 according to exemplary embodiments. As in the above-described embodiment, the pixel may include a plurality of sub-pixels such as a red sub-pixel Pr, a green sub-pixel Pg, and a blue sub-pixel Pb.

Each of the red, green, and blue sub-pixels Pr, Pg, and Pb includes a first region 31 and a second region 32′. The first region 31 includes a pixel circuit unit 311 and a light emitting unit 312, and the pixel circuit unit 311 and the light emitting unit 312 may be disposed adjacent to each other while not overlapping each other.

Unlike in the embodiments of FIGS. 2 and 3 described above, according to the current embodiment of FIG. 5, the first region 31 includes the second region 32′ through which external light is transmitted. That is, the second region 32′ is overlapped with the light emitting unit 312 of the first region 31, and accordingly a surface area of the light emitting unit 312 may be increased.

The second region 32′ may be converted into a transmission mode or a non-transmission mode by switching of the light transmittance converter 5.

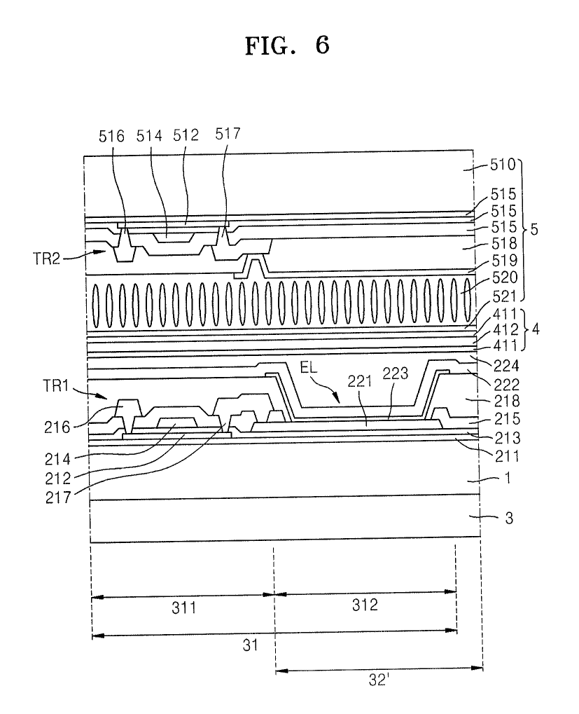

FIG. 6 is a cross-sectional view of a sub-pixel from among the red, green, and blue sub-pixels Pr, Pg, and Pb of FIG. 5. Referring to FIG. 6, the light transmittance converter 5 is a liquid crystal display device.

According to the embodiment of FIG. 6, a control electrode 519 may be formed at a position to overlap with a first electrode 221. A circuit unit electrically connected to the control electrode 519 including a second thin film transistor TR2 is disposed not to overlap with the first electrode 221. The other elements are substantially the same as those in the previous embodiments, and thus description thereof will not be repeated.

When the light transmittance converter 5, which is a liquid crystal display device, is in an external light block mode, the control electrode 519 is turned on (or off) so that transmission of external light through a second region 32′ is blocked by liquid crystals 520. When the light transmittance converter 5 is in an external light transmission mode, the control electrode 519 is turned off (or on) so that external light may be transmitted through the second region 32′.

The external light transmission mode may also be designed to operate only when an organic light emitting device is turned off, and as external light is transmitted accordingly, a decrease in a light emission efficiency of the organic light emitting device due to transmission of external light may be reduced and/or prevented.

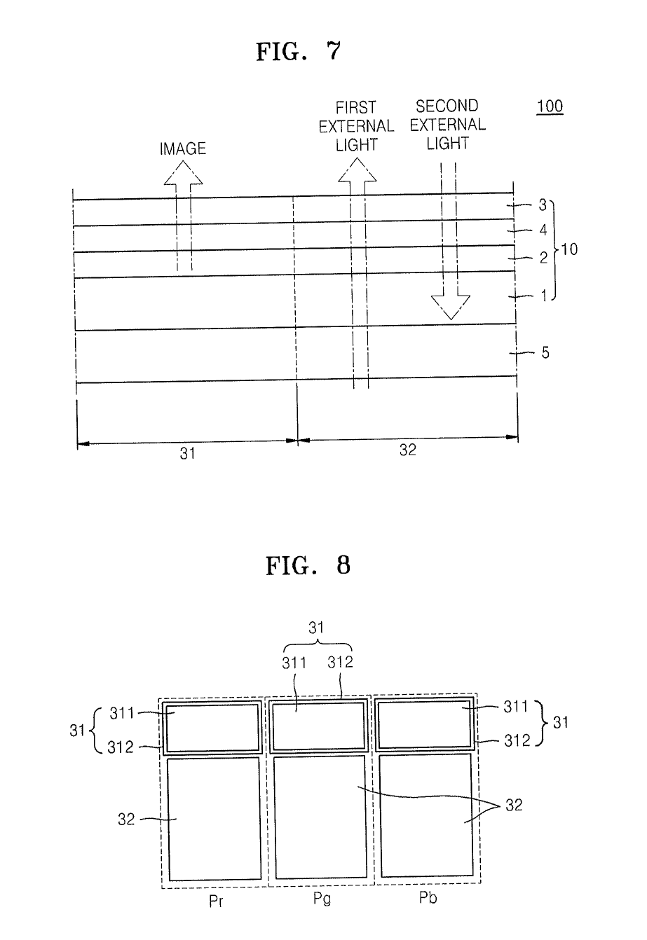

FIG. 7 is a schematic cross-sectional view of a display device 100 according to another exemplary embodiment.

The display device 100 illustrated in FIG. 7 may be an organic light emitting display device including a display unit 10 of a top emission type, which is different from the display device 100 illustrated in FIG. 1. Accordingly, an optical filter 3 is disposed outside an encapsulation structure 4 toward which the display unit 10 emits light. A light transmittance converter 5 is disposed outside the first substrate 1 toward which the display unit 10 does not emit light. The other elements are the same as those in the previous embodiments, and thus description thereof will not be repeated.

According to the embodiment of FIG. 7, when the light transmittance converter 5 is in an external light transmission mode, a user who is located at a place where an image is formed may observe an image on the outer side of the first substrate 1, e.g., through first external light that transmits toward the outer side of the encapsulation structure 4 to the outer side of the first substrate 1. Also, second external light transmits through the display device 100 and is directed to the opposite side of the user, and thus may not affect a contrast ratio of the display device 100.

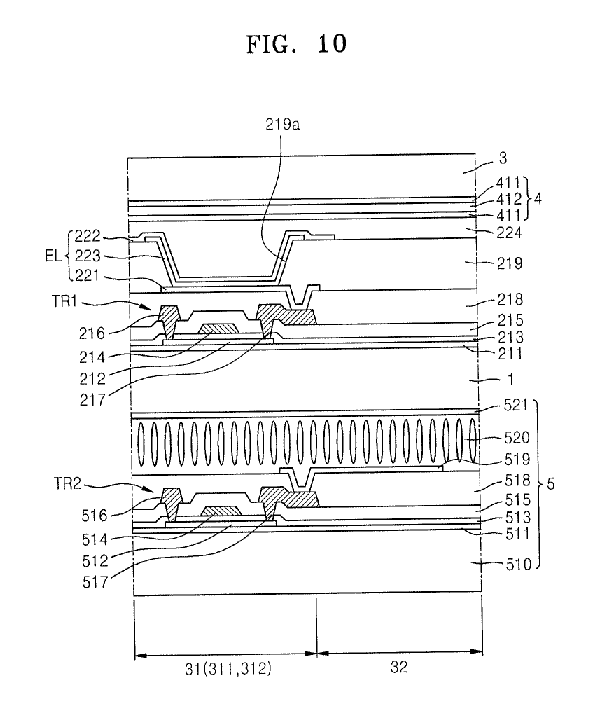

When the light transmittance converter 5 is in an external light block mode, the first external light may not transmit through the display device 100. However, in this mode, second external light which has transmitted through to the outer side of the first substrate 1 on the outer side of the encapsulation structure 4 may be reflected by the light transmittance converter 5 and is emitted again toward the outer side of the second substrate 510 (see FIG. 10), and this may decrease a contrast ratio. Accordingly, exemplary embodiments relate to including an optical filter 3 to reduce the possibility of and/or prevent a decrease in a contrast ratio. An operation of the display device 100 will be described in detail with reference to FIGS. 11 through 13.

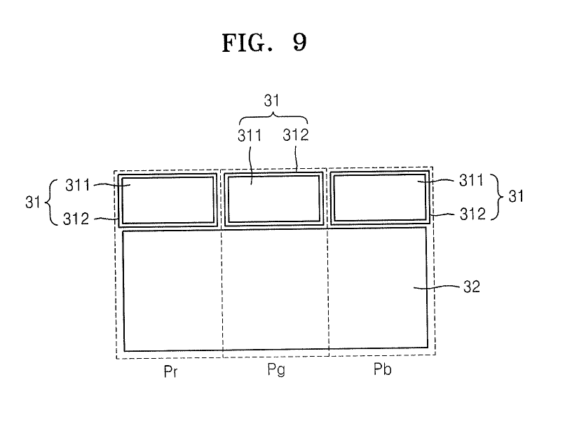

FIG. 8 illustrates an example of a pixel included in the display unit 10 of FIG. 7 according to an exemplary embodiment, and FIG. 9 illustrates another example of a pixel included in the display device 10 of FIG. 7, according to an exemplary embodiment.

Unlike the pixels illustrated in FIGS. 2, 3, and 5, the pixels illustrated in FIGS. 8 and 9 are disposed such that a pixel circuit unit 311 and a light emitting unit 312 included in a first region 31 are disposed to overlap with each other. The light emitting unit 312 emits light toward the encapsulation structure 4, and thus the pixel circuit unit 311 and the light emitting unit 312 may be overlapped with each other. In addition, the light emitting unit 312 may cover the pixel circuit unit 311 including a pixel circuit, thereby reducing the possibility of and/or preventing light interference due to the pixel circuit unit 311. The other elements are the same as those in the embodiments of FIGS. 2, 3, and 5, and thus description thereof will not be repeated.

As illustrated in FIG. 8, a second region 32 may be independently included in each of the red, green, and blue sub-pixels Pr, Pg, and Pb, or may be formed as a single portion over the red, green, and blue sub-pixels Pr, Pg, and Pb as illustrated in FIG. 9.

FIG. 10 is a cross-sectional view of a sub-pixel from among the red, green and blue sub-pixels Pr, Pg, and Pb of FIGS. 8 and 9.

As illustrated in FIG. 10, a first thin film transistor TR1 is disposed in the pixel circuit unit 311, and an organic light emitting diode EL is disposed in the light emitting unit 312.

A first buffer layer 211 is formed on the first substrate 1, and a first semiconductor active layer 212 is formed on the first buffer layer 211. In addition, a first gate insulating layer 213, a first gate electrode 214, and a first interlayer insulating layer 215 are formed on the first semiconductor active layer 212. A first source electrode 216 and a first drain electrode 217 are formed on the first interlayer insulating layer 215. A first insulating layer 218 is formed to cover the first thin film transistor TR1. The first insulating layer 218 may be formed to cover both the first region 31 and the second region 32.

As illustrated in FIG. 10, a first electrode 221 of the organic light emitting diode EL that is electrically connected to the first thin film transistor TR1 is formed on the first insulating layer 218. The first electrode 221 is disposed in the light emitting unit 312 of the first region 31, and is overlapped with the pixel circuit unit 311 and to cover the pixel circuit unit 311.

A second insulating layer 219 formed of an organic and/or inorganic insulating material is formed on the first insulating layer 218. The second insulating layer 219 has a third opening portion 219a, that covers edges of the first electrode 221 and exposes the central portion of the first electrode 221. Meanwhile, the second insulating layer 219 may be included to cover the first region 31, but is not necessarily included to cover the whole first region 31 but it is sufficient if the second insulating layer 219 covers at least a portion of, particularly, the edges of the first electrode 221.

Although not shown in FIG. 10, the second insulating layer 219 may not be disposed on the second region 32. When the second insulating layer 219 is not formed on the second region 32, an external light transmission efficiency of the second region 32 may be further increased.

An organic layer 223 and a second electrode 222 may be sequentially stacked on a portion of the first electrode 221 that is exposed through the third opening 219a. According to an exemplary embodiment, the first electrode 221 may be formed of a stacked structure including a transparent conductor and a reflection layer. The transparent conductor may be formed of ITO, IZO, ZnO, or In₂O₃ having a high work function. The reflection layer may include at least one metal selected from Ag, Mg, Al, Pt, Pd, Au, Ni, Nd, Ir, Cr, Li, Ca, Mo, and an alloy thereof. The first electrode 221 is formed in the first region 31.

The second electrode 222 may be a semi-transmissive/semi-reflective electrode. The second electrode 222 may be formed of, e.g., Ag, Mg, Al, Pt, Pd, Au, Ni, Nd, Ir, Cr, Li, Ca, Mo, or an alloy thereof. The second electrode 222 may be formed of a thin film having a thickness of about 100 Å to about 500 Å so as to obtain a high transmittance. The organic light emitting diode EL may be a top emission type in which an image is formed toward the second electrode 222.

A protection layer 224 is formed on the second electrode 222, and an encapsulation structure 4 including at least one first layer 411 and at least one second layer 412 is formed on the protection layer 224. An optical filter 3 may be disposed on the encapsulation structure 4.

A light transmittance converter 5 is formed on a lower surface of the first substrate 1.

A common electrode 521 is formed of a transparent conductor and arranged on the lower surface of the first substrate 1. A circuit unit including a second thin film transistor TR2 is formed on a surface of the second substrate 510 facing the first substrate 1, and then a passivation layer 518 and a control electrode 519 are sequentially formed thereon. Then, the first substrate 1 and the second substrate 510 are adhered to each other while including a predetermined gap therebetween such that the liquid crystals 520 are implanted between the first substrate 1 and the second substrate 510.

According to the current embodiment, the display device 100 of a top emission type including the display unit 10 and the light transmittance converter 5 may be manufactured using a simple and cost-effective process while reducing the total thickness of the display device 100.

FIGS. 11 through 13 illustrate a method of operating a display device 100 according to respective modes according to an exemplary embodiment.

The display device 100 may be operable in three different modes, which are classified according to light reflectivity of a light transmittance converter 5, and the light reflectivity may be determined according to a power source applied to the light transmittance converter 5.

Referring to FIG. 11, a first mode in which the light transmittance converter 5 transmits all of light is illustrated. In the first mode, first power is applied to the light transmittance converter 5.

An image 60 is emitted from the display unit 10 in a direction D1. A user located in a direction in which the image 60 is emitted may see an object that is disposed on the outer side of the light transmittance converter 5 via first external light 61 that transmits through the display device 100.

Meanwhile, the second external light 62 may transmit through the optical filter 3, the display unit 10, and the light transmittance converter 5, which is transparent, in a direction D2. However, second external light 62′ that has transmitted through the optical filter 3 may become circularly polarized light that rotates in a predetermined direction.

Referring to FIG. 12, a second mode in which the light transmittance converter 5 does not transmit but blocks or reflects light is illustrated. In the second mode, second power that is different from the first power is applied to the light transmittance converter 5.

An image 60 is emitted in the direction D1 in the display unit 10. A user that is located in a direction in which the image 60 is emitted may not see an object that is disposed on the outer side of the light transmittance converter 5. Since the light transmittance converter 5 blocks or reflects light, the first external light 61 does not transmit through the display device 100 in the direction D1.

Accordingly, the second external light 62 may transmit through the optical filter 3 and the display unit 10 in the direction D2. The second external light 62′ that has transmitted through the optical filter 3 becomes circularly polarized light that rotates in a predetermined direction. The second external light 62′, e.g., all of the second external light 62′, is reflected by the light transmittance converter 5 in the direction D1 to become second external light 62″. A rotation direction of the second external light 62″ that is reflected by the light transmittance converter 5 is reversed, and the second external light 62″ becomes circularly polarized light that rotates in a direction that is different from that of the second external light 62′. Accordingly, the second external light 62″ may transmit through the display unit 10, which is transparent, but is not able to transmit through the optical filter 3.

According to the current embodiment, as the second external light 62″ that is reflected by the light transmittance converter 5 does not transmit through the optical filter 3, the second external light 62″ does not reach the user who is at a place where the image 60 is emitted. Accordingly, external light reflection may substantially disappear and/or disappear and a highest contrast ratio of the display device 100 may be obtained. Accordingly, by using the display device 100 as described above, a black color may be accurately represented without external light reflection in a bright environment.

Referring to FIG. 13, a third mode in which the light transmittance converter 5 transmits a portion of light and blocks or reflects the other portion of the light at the same time is illustrated. A sum of reflectivity and transmittance of the light transmittance converter 5 is about 1 or 1. In the third mode, third power that is different from the first power and the second power is applied to the light transmittance converter 5.

An image 60 is emitted from the display unit 10 in a direction D1. A user located in a direction in which the image 60 is emitted may see an object located on the outer side of the light transmittance converter 5 to some extent. This is possible because the light transmittance converter 5 transmits a portion of the first external light 61 and reflects the other portion thereof. First external light 61′ that has transmitted through the light transmittance converter 5 proceeds in the direction D1 to transmit through the display unit 10 and the optical filer 3 and reaches the user. First external light 61″ is reflected by the light transmittance converter 5, and a sum of reflectivity and transmittance of the light transmittance converter 5 is 1 (or 100%).

The second external light 62 may transmit through the optical filter 3 and the display unit 10 in a direction D2. Second external light 62′ that has transmitted through the optical filter 3 becomes circularly polarized light that rotates in a predetermined direction. A portion of the second external light 62′ is reflected by the light transmittance converter 5 in the direction D1, and the other portion of the second external light 62′ transmits through the light transmittance converter 5 in the direction D2 to be second external light 62″. Here, since the sum of transmittance and reflectivity of light of the light transmittance converter 5 is 1 (or 100%), an addition of an amount of the second external light 62″ and an amount of the second external light 62′″ becomes the second external light 62′. A rotation direction of the second external light 62″ reflected by the light transmittance converter 5 is reversed, and the second external light 62″ becomes circularly polarized light that rotates in a direction different from the second external light 62′. Accordingly, the second external light 62″ transmits through the display unit 10 but not through the optical filter 3. In addition, the second external light 62′″ that has transmitted through the light transmittance converter 5 is circularly polarized light that rotates in the same direction as the second external light 62′.

According to the current embodiment, as the second external light 62″ reflected by the light transmittance converter 5 does not transmit through the optical filter 3, the second external light 62″ does not reach the user who is located at the side toward which the image 60 is emitted. Accordingly, even in the third mode in which the light transmittance converter 5 is semi-transmissive, external light reflection substantially disappears and the contrast ratio of the display device 100 may not decrease.

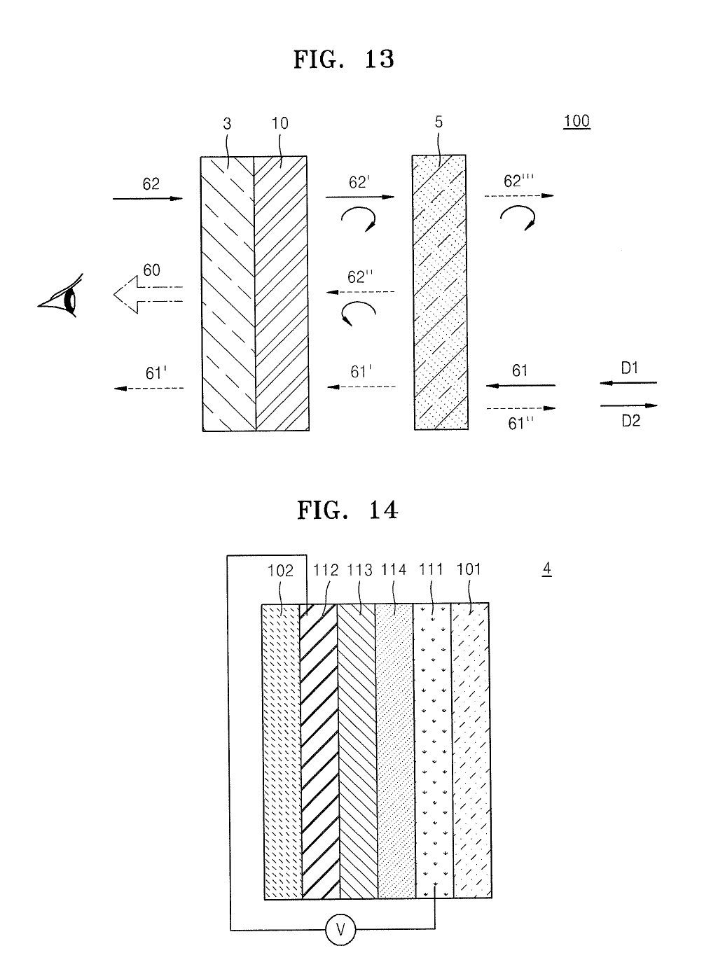

According to the above embodiments, a liquid crystal device is used as the light transmittance converter 5, but the embodiments are not limited thereto. For example, as illustrated in FIG. 14, an electrochromic device may be used as the light transmittance converter 5.

FIG. 14 is a schematic view of a light transmittance converter 5 included in a display device 100 according to an exemplary embodiment. The light transmittance converter 5 of FIG. 14 is a type of an electrochromic device but the embodiments are not limited thereto. For example, an electrochromic device having various structures may be used.

Referring to FIG. 14, the electrochromic device includes a pair of transparent electrode layers 111 and 112 to which power is applied, and an electrochromic material layer 113 included between the transparent electrode layers 111 and 112.

The transparent electrode layers 111 and 112 may include a transparent conductive material such as ITO, IZO, ZnO, or In₂O₃. Substrates 101 and 102 may be further included on outer portions of two sides of the transparent electrode layers 111 and 112.

The electrochromic material layer 113 includes an electrochromic material, e.g., whose phase is changed by a current or voltage applied for the transparent electrode layers 111 and 112 to thereby adjust light reflectivity thereof. Examples of the electrochromic material include magnesium (Mg), nickel (Ni), palladium (Pd), aluminum (Al), tantalum pentoxide (Ta₂O₅), HxWO₃, tungsten oxide (WO₃), and nickel oxide (NiOxHy).

When predetermined power is applied between the transparent electrode layers 111 and 112 of the electrochromic device, the electrochromic material of the electrochromic device reacts with ions or electrons of an electrolyte solution and the electrochromic device changes from a transparent phase to a mirror phase. For example, when the first power is applied, a light transmittance converter 5 is transparent. When the second power is applied, the light transmittance converter 5 exhibits metal-reflecting properties like an opaque mirror. When the third power is applied, the light transmittance converter 5 may exhibit the properties of a semi-transparent mirror. An amount of power and a degree in variation of reflectivity of the light transmittance converter 5 may be determined during the manufacture of products, and as these details are known in the art, detailed description thereof will be omitted in order not to obscure the essence of the embodiments.

The configuration of the electrochromic device is not limited thereto, e.g., additional layers 114 such as a catalyst layer including, e.g., palladium (Pd), a buffer layer including, e.g., aluminum (Al), or an electrolyte layer that facilitates ion conduction of an electrochromic material may be further stacked on the electrochromic material layer 113. These layers may increase an electrochromic efficiency or may stabilize the electrochromic device.

By way of summation and review, a display devices such as an organic light emitting display device may be formed as a transparent display device, e.g., by making a thin film transistor in a transparent form in the organic light emitting display device. Further, a transmission area (or transmission window) may separately form a pixel area in the transparent display device.

However, the transparent display device has only a fixed transmittance; and thus if a user wants to adjust transmittance of the transparent display device, it is difficult to do so; and a contrast ratio thereof is decreased due to reflection of external light.

Embodiments relate to a display device capable of being operated as a transparent display device and a method of operating the same. Embodiments also provide a display device and a method of operating the display device whose transmittance may be adjusted, e.g., according to modes, and in which a decrease in a contrast ratio (of the display device) due to external light reflection may be reduced. Embodiments also provide a display device that may be manufactured easily and at reduced cost, and a method of operating the display device.

Exemplary embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the present invention as set forth in the following claims.

What is claimed is:

1. A display device, comprising:
a first substrate;
a display unit that is on a first surface of the first substrate and that includes a plurality of pixels, each of the pixels including a first region from which light is emitted in a first direction and a second region, adjacent to the first region, through which external light is transmitted;
an encapsulation structure that contacts the first surface of the first substrate so as to cover and encapsulate the display unit, and that includes at least one first layer having an inorganic material and at least one second layer having an organic material; and
a light transmittance converter that is adjacent to the first substrate or the encapsulation structure, that is on an outer side of the display unit in a second direction that is opposite to the first direction, and that converts transmittance of the external light transmitted through the second region.

2. The display device of claim 1, wherein each of the pixels in the display unit includes:
a pixel circuit unit that is on the first surface of the first substrate, that includes at least one thin film transistor, and that is arranged in the first region,
a first electrode that is electrically connected to the pixel circuit unit, that is in the first region, that is arranged adjacent to the pixel circuit unit to be in a non-overlapping relationship with the pixel circuit unit, and that includes a transparent conductive material,
a second electrode that faces the first electrode and that is arranged at least in the first region, and
an organic layer that is interposed between the first electrode and the second electrode and that includes a light emitting layer.

3. The display device of claim 2, wherein the light transmittance converter is arranged on the outer side of the encapsulation structure.

4. The display device of claim 3, wherein the light transmittance converter includes:
a common electrode that is adjacent to the encapsulation structure,
a second substrate that faces the encapsulation structure,
a plurality of control electrodes that are on a portion of the second substrate facing the encapsulation structure and that are arranged to overlap with the second region, and
liquid crystals between the common electrode and the second substrate.

5. The display device of claim 2, further comprising an optical filter that is adjacent to a second surface of the first substrate.

6. The display device of claim 2, wherein the second region overlaps the first region.

7. The display device of claim 1, wherein each of the pixels in the display unit includes:
a pixel circuit unit that is on the first surface of the first substrate, that includes at least one thin film transistor, and that is in the first region,
a first electrode that is electrically connected to the pixel circuit unit, is in the first region so as to overlap the pixel circuit unit to cover the pixel circuit unit, and that includes a reflection layer having a conductive material that reflects light,
a second electrode that is light-transmissive so as to emit light in a direction opposite to the first electrode and that faces the first electrode, and
an organic layer that is between the first electrode and the second electrode and that includes a light emitting layer.

8. The display device of claim 7, wherein the light transmittance converter is adjacent to a second surface of the first substrate.

9. The display device of claim 8, wherein the light transmittance converter includes:
a common electrode that is adjacent to the second surface of the first substrate,
a second substrate that faces the second surface of the first substrate,
a plurality of control electrodes that are on a portion of the second substrate facing the first substrate and that are arranged to overlap with the second region, and
liquid crystals between the common electrode and the second substrate.

10. The display device of claim 7, further comprising an optical filter that is adjacent to the encapsulation structure.

11. The display device of claim 1, wherein in the light transmittance converter, a sum of reflectivity and transmittance of the external light is 1.

12. The display device of claim 1, wherein the light transmittance converter includes:
a pair of transparent electrode layers to which power is applied, and
an electrochromic layer that is arranged between the pair of transparent electrode layers and that includes an electrochromic material, a phase of the electrochromic material being changeable by power applied to the pair of transparent electrode layers to adjust light reflectivity of the electrochromic layer.

13. A method of operating a display device, the display device including:
a first substrate,
a display unit that is on a first surface of the first substrate and that includes a plurality of pixels, each of the pixels including a first region from which light is emitted in a first direction and a second region, adjacent to the first region, through which external light is transmitted,
an encapsulation structure that contacts the first surface of the first substrate so as to cover and encapsulate the display unit, and that includes at least one first layer having an inorganic material and at least one second layer having an organic material, and
a light transmittance converter that is adjacent to the first substrate or the encapsulation structure, that is on an outer side of the display unit in a second direction that is opposite to the first direction, and that converts transmittance of external light transmitted through the second region, the method comprising:
implementing one of a first mode, a second mode, and a third mode by adjusting transmittance of the external light that transmits through at least the second region by applying first through third powers that are different from one another to the light transmittance converter.

14. The method of claim 13, wherein the first mode includes:
applying the first power to the light transmittance converter,
displaying an image in the first direction by way of the display unit, and
allowing the external light to be transmitted through the display unit and the light transmittance converter in the first direction.

15. The method of claim 13, wherein the second mode includes:
applying the second power to the light transmittance converter,
displaying an image in the first direction by way of the display unit, and
blocking transmittal of the external light through the display unit in the first direction.

16. The method of claim 13, wherein the third mode includes:
applying the third power to the light transmittance converter,
displaying an image in the first direction by way of the display unit,
allowing a portion of the external light to be transmitted through the display unit in the first direction, and
allowing another portion of the external light to be reflected by the light transmittance converter in the second direction.

17. The method of claim 16, wherein a sum of transmittance and reflectivity of the external light is 1.
